(19) United States
(12) Patent Application Publication
(10) Pub. No.: US 2008/0180107 A1
(43) Pub. Date: Jul. 31, 2008

(54) CABLE TESTER FOR STAGE LIGHTING ENVIRONMENT

(75) Inventors: Robin Lee, Hamburg, NJ (US); Chris Conti, West New York, NJ (US); John Covington, Carrollton, TX (US)

Correspondence Address: Law Office of Scott C Harris, PO Box 1389, Rancho Santa Fe, CA, 92067, US

(73) Assignee: Production Resource Group L.L.C, New Windsor, NY (US)

(21) Appl. No.: 11/940,263

(22) Filed: Nov. 14, 2007

Related U.S. Application Data
(60) Provisional application No. 60/866,029, filed on Nov. 15, 2006.

(51) Int. Cl. G01R 31/02

(52) U.S. Cl. 324/508

(57) ABSTRACT

A cable testing assembly includes a plurality of different connectors thereon. The different connectors can be automatically used to automatically test a wire by coupling the cable between two different connectors. The testing then switches power to different pins in the connectors and automatically detests continuity and short-circuit among those connectors. The results can be displayed and/or printed on a label. In addition to the continuity test, the system can automatically detects things like wrong gauge, pin placement, links, and capacitance. The connectors can be arranged by power handling connectors, and signal handling connectors.

The present application claims priority from Provisional application No. 60/866,029, filed Nov. 15, 2006, the disclosure of which is herewith incorporated by reference.

### BACKGROUND

Stage lighting equipment is often rented. A rental company may maintain a stock of products and accessories intended for rental to customers. A customer doing a show rents the parts that they want. At the end of the show, all of the parts and materials are returned to the rental company. The rental company will rerent them.

The rental company must maintain a significant stock of parts and accessories in order to support any desired rental contract. Many of the parts and accessories had been previously used by other customers, and hence must be tested prior to being re-rented.

### SUMMARY

The present application describes a cable tester for use in an environment that automatically tests cables of different types as part of rental company inventory. The tested cables can then be automatically characterized and can be re-rented.

### BRIEF DESCRIPTION OF THE DRAWINGS

These and other aspects will now be described in detail with reference to the accompanying drawings wherein:

FIG. 1 illustrates a block diagram of a cable testing system;

FIG. 2 illustrates a flowchart of operation of the cable testing system; and

FIG. 3 shows an exemplary cable tester panel for a rack mount.

### DETAILED DESCRIPTION

The general structure and techniques, and more specific embodiments which can be used to effect different ways of carrying out the more general goals, are described herein.

The basic concept of the system uses a tester with a breakout box and an automatic computer monitoring the different cables connected to the different connections.

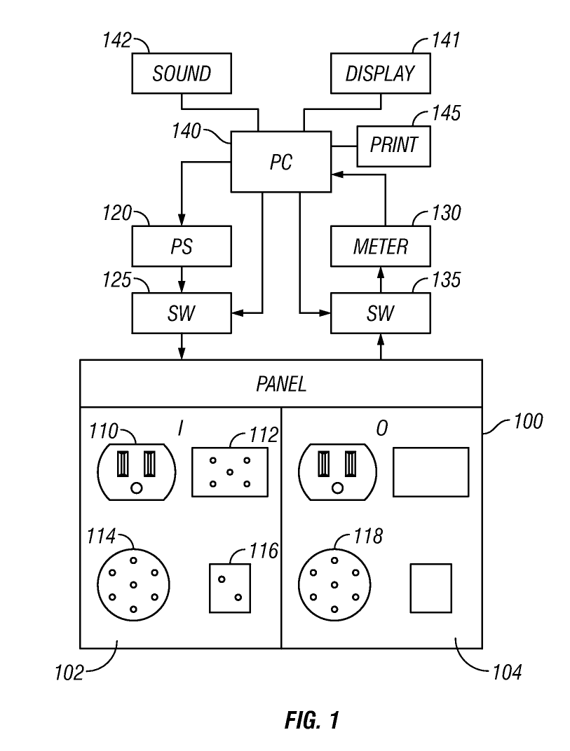

FIG. 1 illustrates an embodiment. A panel 100 is formed with a number of cable connections of various types. The panel is divided into input side 102 and output side 104, although it should be understood that the input and output are relative, since cables are almost exclusively bidirectional. A cable is connected between one of the connectors on side 102 and one of the connectors on side 104.

The connectors on the different panels may include every connector that is within the rental company's inventory. For example, this may include, without limitation, XLR connectors, 19 way Socapex connectors, 3 way connectors, Edison connectors, “stage pin” connectors, coupled twist lock connectors, microphone connectors, computer connectors, and ethernet and other RJ style connectors. The panels 102 and 104 can include, without limitation, each of these connectors. More generally, the panel may include round data style connectors such as the XLR connectors shown as 110; rectangular multi-pin connectors shown as 112; round multipin power and/or power and signal connectors shown as 114 and square data style connectors shown as 116. For maximum usability, each connector on the input side 102 is replicated on the output side 104.

A power supply 120 is connected to the panel, and the panel is also connected to a meter 130. The power supply supplies power, for example, to pins of the input connectors, and the meter 130 receives the resulting power output from the output connector. The power supply 120 and meter 130 are preferably digitally controllable and/or monitorable. Switch box 125 switches the output of the power supply to pin or pins of connectors on the input panel 102. Analogously, switch box 135 switches corresponding pins from the output panel 100 to the meter 130.

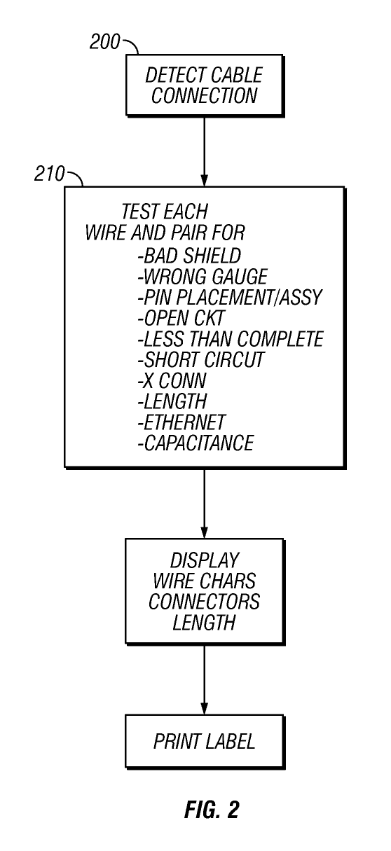

A personal computer 140 controls the output power from power supply 120 and controls the switching from switchboxes 125 and 135. The PC operates the flowchart shown in FIG. 2 herein. The PC may also be connected to a label printer 145 which prints labels for the cables once they are connect-tested.

The PC 140 controls the operation according to the flowchart of FIG. 2. At 200, a cable connection is detected. This may be detected manually, for example by pressing a start button, or can be done by an automatic polling technique where each pin of each connector is applied with a small voltage (for example 5 V) and each pin of each connector on each side is tested for a conducted response. This automatically detects a cable unless the cable is completely open-circuited; in which case no detection would be made.

Once the cable is detected, each wire in each side of the connector is tested for various things. According to FIG. 2, each wire is to be tested for:

Bad shield. This may operate by testing for a connection between the wire and the shield, a connection between any of the wires and ground, or by producing an RF signal to a cable, detecting whether an RF output has been produced. Other techniques of detecting a bad shield may also be used.

Wrong gauge wire. A conventional test for wire gauge may be used. For example, this may use an AC current, a voltage drop test, or the like. Since the computer has information indicating the connector type, it also can use that information to determine the desired gauge. The detected gauge from this test is compared against the desired gauge.

Pin placement and assembly. For each pin in the input connector, the wires should extend to the corresponding pin in the output connector. For example, if a wire is connected to pin 1 in input connector 114, it should correspondingly go to pin 1 in output connector 118. This test automatically applies a voltage into each wire on the input, and tests to see if the voltage is coming out on the same wire on the output.

Short-circuit test. As part of the above pin placement and assembly, a voltage is connected to one of the wires on connector 114. All of the other wires on connector 114, as well as all the wires in the corresponding output connector 118, are tested to determine if the same voltage is found on any of those wires. The voltage occurring on the wrong wires indicates that there is a short-circuit.

Less than complete circuit. Each pin in the input connector receives a voltage, for example 12 V or 100 V. The corresponding pin in the output connector is also tested to determine the voltage. If the output voltage is not close in value to the input, e.g., if the voltage drop is more than 10%, it means that the circuit is less than complete.

Cross connection. Any pin in one connector must be connected to a corresponding pin in the other connector. A cross connection error occurs when the pins are incorrectly connected.

Length detection. A conventional length detector can be used to determine the length of the cable. Different techniques of determining cable length are known including time of flight systems, voltage waveform systems, and the like.

Ethernet test. If the cable includes an ethernet connection, conventional ethernet testing can be carried out.

Capacitance test. The capacitance of the cable is also tested. Capacitance can be compared against the maximum allowable capacitance for the cable type and/or connector type.

All of these tests may be automatically conducted. Other tests may also be detected.

In one embodiment, an off-the-shelf cable tester can be used, such as the Cirrus touch 1 cable tester. In this case, the elements 120, 125, 130, 135 at 140 may be replaced by the cable tester itself.

The results are displayed on a display screen 141, which may indicate the results of the test, the type of cable found, pass/fail, and any other relevant characteristics. A special buzzer may sound if the cable fails any crucial tests, to provide audible indication to the tester that the cable cannot be used.

The system automatically detects the cable characteristics, and a printer 145 may print a label which indicates the type and length of the cable as well as its characteristics. If desired, the printer may also include a barcode printer.

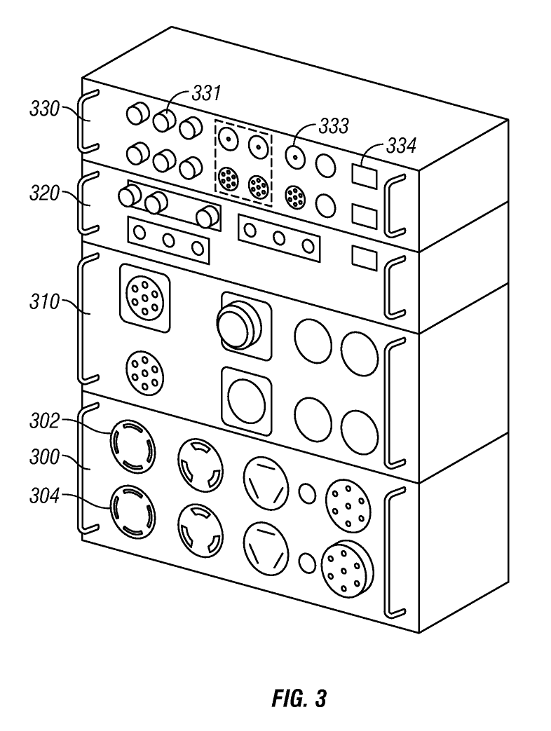

FIG. 3 shows an exemplary cable tester for a rack mount configuration. In the configuration shown in FIG. 3, each of a plurality of different connectors are located having both male and female versions of the connector. The bottommost rack portions 300 includes power connectors, and shows for example a four pin male connector 302 and a four pin female connector 304. Other kinds and types of power connectors are also provided, with the male version on the top row and the female version on the bottom row. Rack 310 includes numerous multi-pin connectors. Rack 320 includes a number of different signal style connectors, and rack 330 similarly includes signal style connectors. For example, the connectors 331 may be BNC connectors and F-style connectors, the connectors 333 may be DMX style connectors, and the connectors 334 may be ethernet connectors. Each of these connectors can be tested in an analogous way to that described above.

The general structure and techniques, and more specific embodiments which can be used to effect different ways of carrying out the more general goals are described herein.

Although only a few embodiments have been disclosed in detail above, other embodiments are possible and the inventors intend these to be encompassed within this specification. The specification describes specific examples to accomplish a more general goal that may be accomplished in another way. This disclosure is intended to be exemplary, and the claims are intended to cover any modification or alternative which might be predictable to a person having ordinary skill in the art. For example, the above describes special kinds of tests, but it should be understood that other tests could also be used. In addition, while the other above describes certain kinds of connectors which are believed to be the most common connectors, it should be understood that other connectors may similarly be used. Moreover, while the above contemplates that most cables lead from one connector type to another connector type of the same type, the system may be used to can detect and monitor characteristics of cables that have different input and output connectors.

Also, the inventors intend that only those claims which use the words “means for” are intended to be interpreted under 35 USC 112, sixth paragraph. Moreover, no limitations from the specification are intended to be read into any claims, unless those limitations are expressly included in the claims. The computers described herein may be any kind of computer, either general purpose, or some specific purpose computer such as a workstation. The computer may be a Pentium class computer, running Windows XP or Linux, or may be a Macintosh computer. The computer may also be a handheld computer, such as a PDA, cellphone, or laptop.

The programs may be written in C, or Java, Brew or any other programming language. The programs may be resident on a storage medium, e.g., magnetic or optical, e.g. the computer hard drive, a removable disk or media such as a memory stick or SD media, or other removable medium. The programs may also be run over a network, for example, with a server or other machine sending signals to the local machine, which allows the local machine to carry out the operations described herein.

What is claimed is:

1. A system, comprising:
a panel of connectors, said panel of connectors including at least first, second and third connector sets, each said connector set including a male version of the connector set and a female version of the connector set, at least one of said connector sets being a power-carrying connector and at least another of said connector sets being a signal-carrying connector, and wherein each of said connectors connect to a cable that have multiple wires therein;
at least one cable testing element, selectively connectable to each of said first, second and third connector sets, wherein said cable testing element connects between both said male version and said female version of each said connector set, and wherein cable testing element carries out at least two different and separate tests on multiple wires of said cable, wherein said two different and separate tests include different tests which test different aspects of a cable that is connected to or between one of said connector sets, and a display subsystem, displaying at least one result of said tests.

2. A system as in claim 1, wherein said cable testing element individually tests individual pins of said connector sets, by carrying out at least two different and separate tests on each of a plurality of said individual pins.

3. A system as in claim 2, wherein said cable testing element tests a first pin on a first connector of said connector set, and tests a second pin on a second connector of said connector set, where said second pin is a pin that does not correspond to said first pin, and wherein said test of said second pin checks for a short circuit between said other pins and said individual pin.

4. A system as in claim 1, wherein one of said tests includes proper pin assembly.

5. A system as in claim 1, wherein one of said tests includes a capacitance test.

6. A system as in claim 1, wherein one of said tests includes a wire gauge test.

7. A system as in claim 1, wherein said cable testing element automatically detects that a cable is connected to connectors, and begins said test automatically, between said connectors, when said cable is connected to said connectors.

8. A system as in claim 1, wherein said cable testing element includes at least first and second switching parts, said first switching part connected to each individual pin of a first connector of each said set, and said second switching part connected to each individual pin of a second connector of each said set.

9. A system as in claim 1, further comprising a printer, coupled to receive information from said cable testing element, and printing information about the cable that has been automatically determined by said cable testing element.

10. A system, comprising:
a surface, including a plurality of pairs of connectors thereon, each said pair of connectors having a relationship therebetween, and being a pair of connectors intended to receive a specified type of cable therebetween;
a wire testing part, testing between said pair of connectors to determine characteristics of multiple wires connected therebetween, said characteristics that are tested including at least testing for short-circuit in the wires, testing for cross connection in the wires, and testing for proper continuity in the wires; and
an output system, producing an output signal indicative of said test, wherein said output signal is produced in a way that can be viewed by the user.

11. A system as in claim 10, wherein said output signal can be viewed by printing a label.

12. A system as in claim 10, wherein said output signal can be viewed as an output signal on a display.

13. A system as in claim 10, wherein said wire testing parts further carry out testing at least one test of bad shield, open circuit, a length test and a capacitance test.

14. A system as in claim 10, wherein said wire testing part automatically detects a wire being connected and automatically initiates a test responsive to said wire being connected.

15. A method, comprising:
connecting a cable that has a plurality of separate wires therein between a first connector on a panel, and a second connector on the panel; and
automatically testing at least a plurality of said separate wires responsive to said connecting.

16. A method as in claim 15, wherein said automatically testing automatically begins said testing responsive to automatically detecting that said cable has been connected between said first connector and said second connector.

17. A method as in claim 15, wherein said automatically detecting tests at least each wire in said cable for continuity between a first pin on the first connector and a second proper pin on the second connector, and also for short-circuits to other pins other than said second proper pin on said second connector.

18. A method as in claim 15, further comprising displaying the results of said automatically testing.

19. A method as in claim 15, further comprising printing a label having results of said automatically testing.
